(19) United States
(12) Patent Application Publication
(10) Pub. No.: US 2026/0329026 A1
(43) Pub. Date: Oct. 22, 2026

(54) PHOTONIC CHIP STRUCTURE AND SEMICONDUCTOR PACKAGE COMPRISING THE SAME

(71) Applicant: SAMSUNG ELECTRONICS CO., LTD., Suwon-si (KR)

(72) Inventor: Youngja Kim, Suwon-si (KR)

(73) Assignee: SAMSUNG ELECTRONICS CO., LTD., Suwon-si (KR)

(21) Appl. No.: 19/649,856

(22) Filed: Apr. 16, 2026

(30) Foreign Application Priority Data
Apr. 17, 2025 (KR) 10-2025-0050410

(51) Int. Cl. G02B 6/42; H10W 70/60; H10W 90/00; H10W 90/10; H10W 90/20; H10W 90/28

(52) U.S. Cl. CPC G02B 6/4206; G02B 6/4212; G02B 6/4255; G02B 6/426; G02B 6/4274; H10W 70/611; H10W 90/10; H10W 90/291; H10W 90/297; H10W 90/792; H10W 90/28; H10W 90/401; H10W 90/724; H10W 90/7295

(57) ABSTRACT

A photonic chip structure includes a photonic integrated circuit chip, an electronic integrated circuit chip connected to the photonic integrated circuit chip, a photonic block on the photonic integrated circuit chip and configured to provide a path for optical signals, a coating layer on at least a side surface of the photonic block and configured to suppress scattering of optical signals inside the photonic block, and a molding layer on the photonic integrated circuit chip and a side surface of the photonic block, the coating layer being between the molding layer and the photonic block.

### CROSS-REFERENCE TO RELATED APPLICATION

This application claims priority to Korean Patent Application No. 10-2025-0050410, filed on Apr. 17, 2025, in the Korean Intellectual Property Office, the disclosure of which is incorporated by reference herein in its entirety.

### BACKGROUND

Embodiments of the present disclosure relate to a photonic chip structure and a semiconductor package including the same, and more particularly, to a photonic chip structure including a photonic block located on a photonic integrated circuit chip, and a semiconductor package including the same.

With the advancement of photonic integrated circuit chip (PIC) technology, technologies are being actively developed to integrate optical devices, which perform the function of converting optical signals into electrical signals or vice versa, onto semiconductor chips. These optical devices play a key role in various application fields, such as high-speed communications, optical sensors, light detection and ranging (LiDAR), and quantum information processing. Accordingly, packaging technology for integrating and protecting the optical devices is also attracting attention as an important technology.

In particular, a molding packaging process using an epoxy molding compound (EMC) is widely used to protect semiconductor chips containing optical devices from the external environment and to secure mechanical strength and thermal stability. Typically, the EMC consists of epoxy resin and filler, with SiO₂ filler being the most commonly used filler. However, the SiO₂ filler forms an optically non-uniform environment due to a difference in refractive index between the filler and the epoxy resin, which can cause scattered light around the optical devices. This scattered light not only degrades the quality of the optical signals, but also causes optical loss, which can impede optical performance.

### SUMMARY

One or more embodiments provide a photonic chip with minimized optical loss and a semiconductor package including the same.

According to an aspect of one or more embodiment, there is provided a photonic chip structure including a photonic integrated circuit chip, an electronic integrated circuit chip connected to the photonic integrated circuit chip, a photonic block on the photonic integrated circuit chip and configured to provide a path for optical signals, a coating layer on at least a side surface of the photonic block and configured to suppress scattering of optical signals inside the photonic block, and a molding layer on the photonic integrated circuit chip and a side surface of the photonic block, the coating layer being between the molding layer and the photonic block.

According to another aspect of one or more embodiment, there is provided a photonic chip structure including a photonic integrated circuit chip, an electronic integrated circuit chip connected to the photonic integrated circuit chip, a photonic block on the photonic integrated circuit chip and configured to provide a path for optical signals, a coating layer on at least a side surface of the photonic block, the coating layer having a refractive index less than a refractive index of the photonic block, and a molding layer on the photonic integrated circuit chip and on a side surface of the photonic block, the coating layer being between the molding layer and the photonic block.

According to still another aspect of one or more embodiment, there is provided a semiconductor package including a package substrate, a semiconductor chip structure on the package substrate, and a photonic chip structure on the package substrate and spaced apart from the semiconductor chip structure in a horizontal direction, wherein the photonic chip structure includes a photonic integrated circuit chip, an electronic integrated circuit chip connected to the photonic integrated circuit chip, a photonic block on the photonic integrated circuit chip and configured to provide a path for optical signals, a coating layer on at least a side surface of the photonic block and configured to suppress scattering of optical signals inside the photonic block, and a molding layer on the photonic integrated circuit chip and on a side surface of the photonic block, the coating layer being between the molding layer and the photonic block..

According to further still another aspect of one or more embodiments, there is provided a method of manufacturing a photonic chip structure, the method including forming a coating layer on a photonic block, attaching an electronic integrated circuit chip on a photonic integrated circuit chip, attaching the photonic block on which the coating layer is formed to the photonic integrated circuit chip so as to be spaced apart from the electronic integrated circuit chip in a horizontal direction, and forming a molding layer on the photonic integrated circuit chip to seal the electronic integrated circuit chip and the photonic block.

According to one or more embodiments, the forming of the coating layer may include forming a first portion of the coating layer on a side surface of the photonic block and forming a second portion of the coating layer on a portion of a top surface of the photonic block.

According to one or more embodiments, the forming of the coating layer may include forming an opening in the second portion so as not to overlap with a path for optical signals provided from an optical fiber unit disposed above the photonic block.

According to one or more embodiments, the forming of the coating layer may include forming a first portion of the coating layer on a side surface of the photonic block and forming a third portion of the coating layer on a portion of the bottom surface of the photonic block.

According to one or more embodiments, the attaching of the photonic block includes forming an optically clear adhesive on the bottom surface of the third portion of the coating layer to bond the photonic block onto the photonic integrated circuit chip, and a gap may be formed between the optically clear adhesive and a region of the bottom surface of the photonic block that does not overlap the third portion.

According to one or more embodiments, the forming of the coating layer may include forming a first coating layer in contact with the photonic block, and forming a second coating layer in contact with the molding layer, wherein the first coating layer may block scattering of internal optical signals of the photonic block, and the second coating layer may block external light entering the photonic block.

According to one or more embodiments, the first coating layer may be formed of a light-absorbing material.

According to one or more embodiments, the second coating layer may include a light-absorbing material or a light-reflecting material.

According to one or more embodiments, the coating layer may have a refractive index less than a refractive index of the photonic block.

According to one or more embodiments, the method may further include grinding the substrate so as to expose a through electrode within the substrate of the photonic integrated circuit chip, and forming a redistribution structure on the substrate.

### BRIEF DESCRIPTION OF DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of the semiconductor package of FIG. 1 taken along line I-I′;

FIG. 3 is a schematic cross-sectional view of the semiconductor package of FIG. 1 taken along line II-II′;

FIG. 4 is a schematic cross-sectional view of a photonic chip structure according to one or more embodiments;

FIG. 5 is a schematic cross-sectional view of a photonic chip structure according to one or more embodiments;

FIGS. 6A and 6B are schematic cross-sectional views of photonic chip structures according to one or more embodiments;

FIG. 7 is a schematic perspective view of a photonic block and a coating layer of FIG. 6A;

FIGS. 8A, 8B, and 8C are schematic cross-sectional views of photonic chip structures according to one or more embodiments;

FIG. 9 is a schematic cross-sectional view of a photonic chip structure according to one or more embodiments;

FIG. 10 is a schematic cross-sectional view of a photonic chip structure according to one or more embodiments;

FIG. 11 is a schematic plan view of a semiconductor package according to one or more embodiments;

FIG. 12 is a schematic cross-sectional view of the semiconductor package of FIG. 11 taken along line III-III′; and

FIGS. 13, 14, 15, 16, 17, and 18 are schematic diagrams illustrating a process of a method of manufacturing the semiconductor package of FIGS. 1 to 3.

### DETAILED DESCRIPTION

Hereinafter, embodiments are described in detail with reference to the accompanying drawings. The same reference numerals are used for the same components in the drawings, and redundant descriptions thereof are omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Also, the term “and/or” includes any and all combinations of one or more of the associated listed items. For example, an expression, “a and/or b” should be understood as including only a, only b and both a and b.

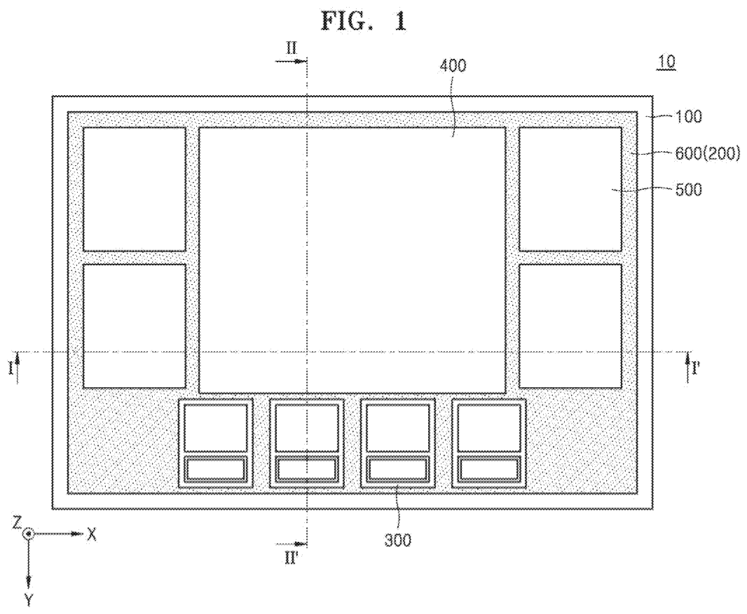

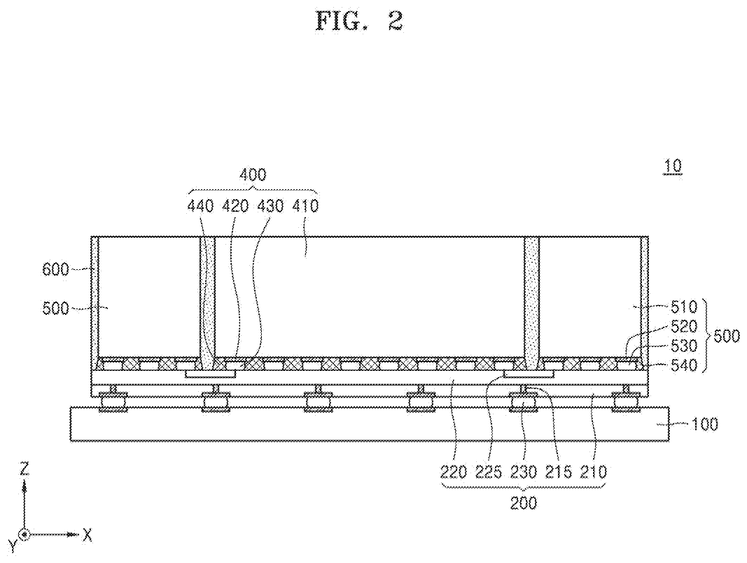

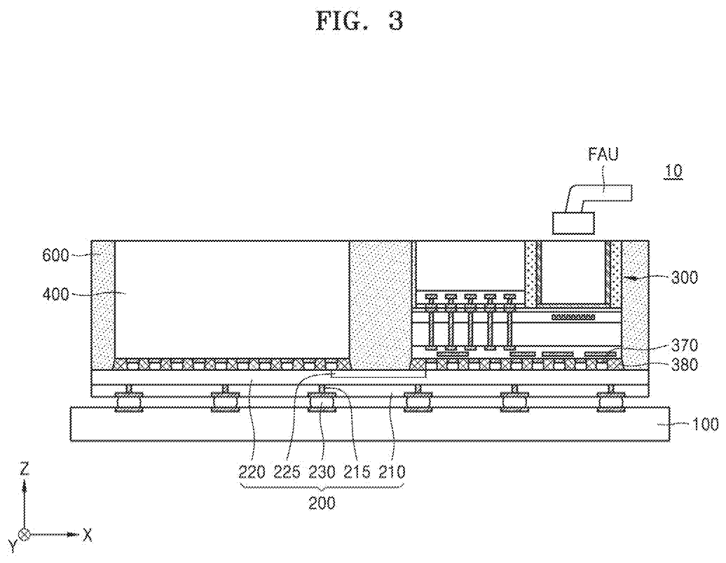

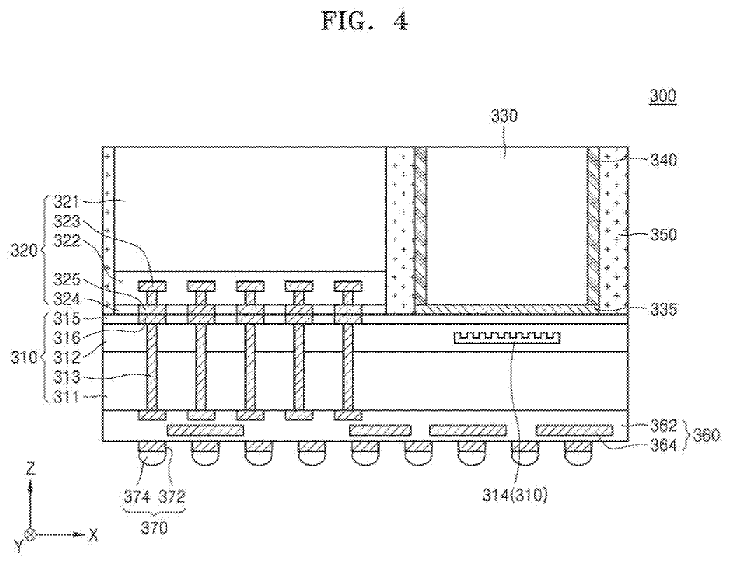

FIG. 1 is a schematic plan view of a semiconductor package 10 according to one or more embodiments. FIG. 2 is a schematic cross-sectional view of the semiconductor package 10 of FIG. 1 taken along line I-I′. FIG. 3 is a schematic cross-sectional view of the semiconductor package 10 of FIG. 1 taken along line II-II′. FIG. 4 is a schematic cross-sectional view of a photonic chip structure 300 according to one or more embodiments.

Referring to FIGS. 1 to 4, the semiconductor package 10 may include a first package substrate 100, a second package substrate 200, photonic chip structures 300, a first chip structure 400, second chip structures 500, and a package molding layer 600. According to one or more embodiments, the semiconductor package 10 may communicate with an external device through optical signals. The semiconductor package 10 may include an optical engine.

Hereinafter, unless otherwise specified, a direction parallel to a top surface of the first package substrate 100 is defined as a first horizontal direction (X direction), a direction perpendicular to the top surface of the first package substrate 100 is defined as a vertical direction (Z direction), and a direction perpendicular to the first horizontal direction (X direction) and the vertical direction (Z direction) is defined as a second horizontal direction (Y direction).

First, the photonic chip structure 300 may include an optical engine that receives and converts optical signals from an external device into electrical signals or transmits internal electrical signals to the outside as optical signals. The photonic chip structure 300 may be mounted on the second package substrate 200 to be electrically connected to the first chip structure 400 or the second chip structures 500 through the second package substrate 200.

The photonic chip structure 300 may include a photonic integrated circuit chip 310, an electronic integrated circuit chip 320, a photonic block 330, a coating layer 340, a molding layer 350, a redistribution structure 360, and connection terminals 370.

According to one or more embodiments, the photonic integrated circuit chip 310 may include a first substrate 311, a first interlayer insulating layer 312, through electrodes 313, a grating coupler 314, a first passivation layer 315, and first connection pads 316.

The first substrate 311 may include a semiconductor material, such as, for example, silicon (Si) or germanium (Ge). The first substrate 311 may include a top surface and a bottom surface opposite to the top surface. The bottom surface of the first substrate 311 may face the redistribution structure 360. The through electrodes 313 may extend from the top surface to the bottom surface of the first substrate 311. The lower ends of the through electrodes 313 in contact with connection pads may be electrically connected to the redistribution structure 360.

The first interlayer insulating layer 312 may be disposed on the top surface of the first substrate 311. For example, the first interlayer insulating layer 312 may have a constant thickness in the vertical direction (Z direction) and may be formed along the top surface of the first substrate 311. According to one or more embodiments, the first interlayer insulating layer 312 may include an inorganic insulating layer, such as, for example, silicon oxide (SiO) or silicon nitride (SiN). As another example, the first interlayer insulating layer 312 may include a polymer material. As another example, the first interlayer insulating layer 312 may include an insulating polymer or a photo-imageable dielectric (PID). For example, the PID may include at least one of a photosensitive polyimide (PSPI), a polybenzoxazole (PBO), a phenol-based polymer, or a benzocyclobutene-based polymer. The first interlayer insulating layer 312 may be composed of two or more insulating materials stacked on top of each other.

The through electrodes 313 may pass and/or penetrate through the first substrate 311 and the first interlayer insulating layer 312. For example, the through electrodes 313 may extend from the bottom surface of the first substrate 311 to the first connection pads 316.

The through electrode 313 may include a conductive material that may include, for example, copper (Cu), gold (Au), silver (Ag), nickel (Ni), tungsten (W), aluminum (Al), or a combination thereof. In one or more embodiments, the through electrodes 313 may further include a barrier material for preventing the conductive material from diffusing out of the through electrodes 313. The barrier material may include, for example, titanium (Ti), tantalum (Ta), titanium nitride (TiN), tantalum nitride (TaN), or a combination thereof.

Although FIG. 4 shows that the through electrodes 313 pass through the first interlayer insulating layer 312 and are connected to the first connection pads 316, embodiments are not limited thereto. The through electrodes 313 may pass through only the first substrate 311 and may be connected to the first interlayer insulating layer 312. In this case, the first interlayer insulating layer 312 may further include a wiring pattern therein. For example, the wiring pattern may include wiring lines extending in the horizontal direction (X direction and/or Y direction) and a wiring via vertically connecting the wiring lines to electrically connect the through electrode 313 to the first connection pad 316.

The grating coupler 314 may be embedded in the first interlayer insulating layer 312. The grating coupler 314 may be configured to couple the optical signals incident to the photonic block 330 through a fiber array unit (FAU). For example, the optical signals arriving at the grating coupler 314 through the photonic block 330 may be coupled to another waveguide. A waveguide and an optical component may be arranged in the first interlayer insulating layer 312 and the grating coupler 314 may be located in a region of the waveguide. The waveguide, which is a patterned silicon layer, may extend in the first horizontal direction (X direction). In one or more embodiments, the waveguide may include a silicon waveguide including silicon, and the first interlayer insulating layer 312 may include a buried oxide (BOX) layer. However, the waveguide is not limited thereto. The waveguide may be covered by an oxide layer separated from the first interlayer insulating layer 312. The optical component may be connected to the waveguide and may convert optical signals into electrical signals or convert electrical signals into optical signals. The optical component may include a photodetector, a photodiode, and a modulator.

The grating coupler 314 may be arranged to be aligned with the photonic block 330. For example, the grating coupler 314 may be arranged in the first interlayer insulating layer 312 to overlap the photonic block 330 in the vertical direction (Z direction). Although one grating coupler 314 is shown in FIG. 4, a plurality of grating couplers 314 may be provided depending on the arrangement of the FAU on the photonic block 330.

The first passivation layer 315 may be disposed on the first interlayer insulating layer 312. The first passivation layer 315 may protect the first interlayer insulating layer 312 and the lower structure of the photonic chip structure 300. The first passivation layer 315 may include an insulating material, such as silicon carbon nitride (SiCN).

The first connection pads 316 may be disposed on the first interlayer insulating layer 312. For example, the first connection pads 316 may be embedded in the first passivation layer 315, and side surfaces of the first connection pads 316 may be surrounded by the first passivation layer 315. For example, the first passivation layer 315 may be on and contact the side surfaces of the first connection pads 316. In addition, top surfaces of the first connection pads 316 may not be covered by the first passivation layer 315 and exposed. The top surfaces of first connection pads 316 may be located on the same level as the top surface of first passivation layer 315 in the vertical direction (Z direction). The first connection pads 316 may be electrically connected to the through electrodes 313 and may be coupled to the second connection pads 325 of the electronic integrated circuit chip 320.

According to one or more embodiments, the electronic integrated circuit chip 320 may be mounted on the photonic integrated circuit chip 310. The electronic integrated circuit chip 320 may be disposed on the photonic integrated circuit chip 310 and may be spaced apart from the photonic block 330 in the horizontal direction (X direction and/or Y direction). The electronic integrated circuit chip 320 may be configured to interconnect the photonic integrated circuit chip 310 to the chip structures (e.g., the first chip structure 400 and the second chip structure 500). For example, the electronic integrated circuit chip 320 may convert the electrical signals converted by the photonic integrated circuit chip 310 to match the chip structures (e.g., the first chip structure 400 and the second chip structures 500).

In one or more embodiments, a horizontal width of the electronic integrated circuit chip 320 may be less than a horizontal width of the photonic integrated circuit chip 310 in the horizontal direction (X direction and/or Y direction). The footprint of the electronic integrated circuit chip 320 may be less than the footprint of the photonic integrated circuit chip 310.

The electronic integrated circuit chip 320 may include a second substrate 321, a second interlayer insulating layer 322, wiring structures 323, a second passivation layer 324, and second connection pads 325.

The second substrate 321 may include a semiconductor material, such as silicon or germanium. The second substrate 321 may include an active surface and a non-active surface opposite to the active surface. In one or more embodiments, the electronic integrated circuit chip 320 may include a plurality of individual elements used to interface with the photonic integrated circuit chip 310. The plurality of individual elements of the electronic integrated circuit chip 320 may be located on the active surface of the second substrate 321. The active surface of the second substrate 321 may include a bottom surface of the second substrate 321. For example, the electronic integrated circuit chip 320 may include complementary metal-oxide-semiconductor (CMOS) drivers, trans-impedance amplifiers, and the like to perform functions, such as controlling high-frequency signaling of the photonic integrated circuit chip 310.

According to one or more embodiments, the second interlayer insulating layer 322 may be disposed on the top surface of the second substrate 321. For example, the second interlayer insulating layer 322 may have a constant thickness in the vertical direction (Z direction) and may be formed along the top surface of the second substrate 321. According to one or more embodiments, the second interlayer insulating layer 322 may include an inorganic insulating layer, such as SiO or silicon nitride SiN. As another example, the second interlayer insulating layer 322 may include a polymer material. As another example, the second interlayer insulating layer 322 may include an insulating polymer or a PID. For example, the PID may include at least one of a PSPI, a polybenzoxazole (PBO), a phenol-based polymer, or a benzocyclobutene-based polymer. The second interlayer insulating layer 322 may be composed of two or more insulating materials stacked on top of each other.

The wiring structures 323 may be arranged in the second interlayer insulating layer 322. The wiring structures 323 may be connected to individual elements located on the active surface of the second substrate 321. Furthermore, the wiring structures 323 may be electrically connected to the second connection pads 325. According to one or more embodiments, the wiring structure 323 may include wiring lines extending in the horizontal direction (X direction and/or Y direction) and a wiring via vertically connecting the wiring lines to electrically connect the individual element to the second connection pad 325.

The second passivation layer 324 may be disposed on the second interlayer insulating layer 322. The second passivation layer 324 may protect the second interlayer insulating layer 322 and the wiring structures 323. The second passivation layer 324 may include an insulating material, such as SiCN.

The second connection pads 325 may be disposed on the second interlayer insulating layer 322. For example, the second connection pads 325 may be embedded in the second passivation layer 324 and side surfaces of the second connection pads 325 may be surrounded by the second passivation layer 324. For example, the second passivation layer 324 may be on and contact the side surfaces of the second connection pads 325. In addition, bottom surfaces of the second connection pads 325 may not be covered by the second passivation layer 324 and exposed. The bottom surfaces of the second connection pads 325 may be located on the same level as the bottom surface of the first passivation layer 324 in the vertical direction (Z direction). The second connection pads 325 may be electrically connected to the wiring structures 323 and may be coupled to the first connection pads 316 of the photonic integrated circuit chip 310.

In one or more embodiments, the electronic integrated circuit chip 320 may be coupled to the photonic integrated circuit chip 310 by direct bonding. The direct bonding may include, for example, dielectric-to-dielectric bonding, copper-to-copper bonding, and hybrid bonding in which the dielectric-to-dielectric bonding and metal-to-metal bonding are performed together. In this case, the first connection pads 316 may be coupled to the second connection pads 325 by heat diffusion bonding. However, the electronic integrated circuit chip 320 may be electrically connected to the photonic integrated circuit chip 310 by a connection terminal, such as a solder ball, or an adhesive film, such as an anisotropic film (ACF) or a non-conductive film (NCF).

Although FIG. 4 illustrates that the electronic integrated circuit chip 320 is disposed on the photonic integrated circuit chip 310 and is spaced apart from the photonic block 330 in the horizontal direction (X direction and/or Y direction), embodiments are not limited thereto. The electronic integrated circuit chip 320 may be arranged at various locations to be electrically connected to the photonic integrated circuit chip 310. For example, the electronic integrated circuit chip 320 may be arranged side by side with the photonic integrated circuit chip 310 in the horizontal direction (X direction and/or Y direction) on the second package substrate 200 or the electronic integrated circuit chip 320 may be arranged below the photonic integrated circuit chip 310. For example, when the electronic integrated circuit chip 320 is not disposed on the photonic integrated circuit chip 310, a silicon dummy chip may be further arranged at the position of the electronic integrated circuit chip 320 in FIG. 4.

The photonic block 330 may be located on the photonic integrated circuit chip 310. For example, the photonic block 330 may be spaced apart from the electronic integrated circuit chip 320 in the first horizontal direction (X direction) and may be located on the photonic integrated circuit chip 310. The photonic block 330 may be located above the grating coupler 314 of the photonic integrated circuit chip 310 in the vertical direction (Z direction). The horizontal width of the photonic block 330 may be less than the horizontal width of the photonic integrated circuit chip 310 in the horizontal direction (X direction and/or Y direction).

The photonic block 330 may have a constant refractive index. For example, the photonic block 330 may include silicon, glass, or a polymer. An optical path through which external optical signals are transmitted to the photonic integrated circuit chip 310 may be formed in the photonic block 330.

The photonic block 330 may include microlenses. For example, the microlenses may be attached to the top surface of the photonic block 330 or may be integrally formed with the photonic block 330. In addition, for example, the top surface of the photonic block 330 may be recessed concavely to function as the microlenses. When the microlenses are disposed on the top surface of the photonic block 330, the microlenses may be formed in a row or in multiple rows on the top surface of the photonic block 330. The microlens may be formed to correspond to the FAU located above the photonic block 330. In addition, the microlens may be arranged corresponding to the grating coupler 314. The plurality of microlenses may correspond one-to-one with the plurality of grating couplers 314. For example, when the plurality of grating couplers 314 are arranged in a 1×20 array or a 2×20 array on a plane, the plurality of microlenses may likewise be correspondingly arranged in a 1×20 array or a 2×20 array.

The coating layer 340 may be disposed on a surface of the photonic block 330. The coating layer 340 may be formed on at least a portion of the surface of the photonic block 330. The coating layer 340 may suppress the optical signals inside the photonic block 330 from being scattered at the boundary surface of the photonic block 330 and/or prevent the external light of the photonic block 330 other than the optical signals to be transmitted or the scattered light in the molding layer 350 from entering the photonic block 330.

In one or more embodiments, the coating layer 340 may be arranged to surround and/or be provided on the side surfaces of the photonic block 330. As the coating layer 340 is arranged between the photonic block 330 and the molding layer 350 to surround and/or be provided on the photonic block 330, the optical signals inside the photonic block 330 may be suppressed from being randomly reflected at the boundary surface of the photonic block 330. In one or more embodiments, the coating layer 340 may be formed of a light-absorbing material. For example, the coating layer 340 may include, but is not limited to, carbon black, TiN, silicon chromium (SiCr), and a black resin.

In one or more embodiments, the coating layer 340 may allow the optical signals inside the photonic block 330 to be totally reflected at the boundary surface of the photonic block 330. For example, as the coating layer 340 is formed of a material having a refractive index less than that of the photonic block 330, the optical signals inside the photonic block 330 may be totally reflected at the boundary between the photonic block 330 and the coating layer 340.

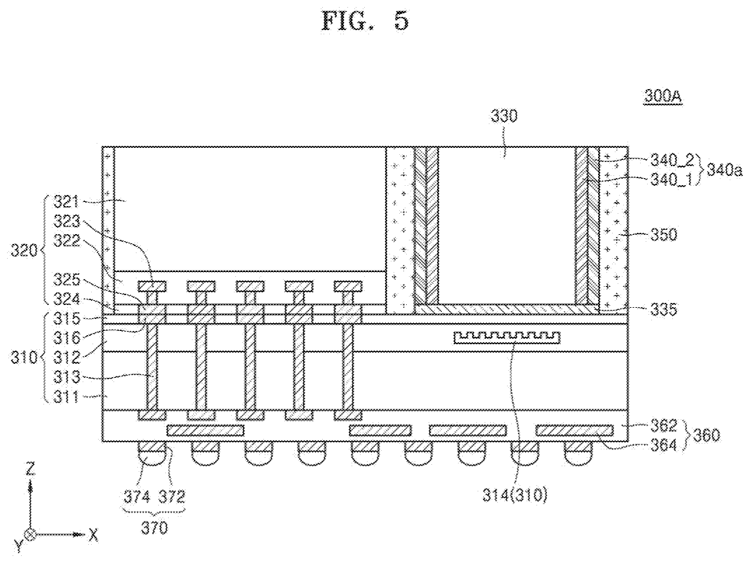

Although FIG. 4 shows that the coating layer 340 is disposed only on the side surfaces of the photonic block 330, embodiments are not limited thereto. For example, the coating layer 340 may be arranged to be provided on and/or cover a portion of the top surface and/or a portion of the bottom surface as well as the side surfaces of the photonic block 330. In addition, although the coating layer 340 is illustrated as being formed of a single layer in FIG. 4, but is not limited thereto. The coating layer 340 may include a plurality of layers. Various embodiments are described in detail with reference to FIGS. 5 to 8C.

The bottom surface of the photonic block 330 may be provided with a photonic adhesive layer 335. The photonic block 330 may be attached to the photonic integrated circuit chip 310 with the photonic adhesive layer 335 arranged between the photonic block 330 and the photonic integrated circuit chip 310. The photonic adhesive layer 335 may attach the photonic block 330 onto the photonic integrated circuit chip 310 such that optical signals passing through the photonic block 330 may be transmitted to the grating coupler 314. In one or more embodiments, the photonic adhesive layer 335 may include an optically clear adhesive (OCA) or an optical glue. For example, the photonic adhesive layer 335 may be formed of an acrylic resin, a silicone resin, a polyurethane resin, or an epoxy resin.

The molding layer 350 may seal the electronic integrated circuit chip 320 and the photonic block 330 on the photonic integrated circuit chip 310. The molding layer 350 may be provided on and/or cover the top surface of the first passivation layer 315 of the photonic integrated circuit chip 310 and surround and/or be provided on side surfaces of the electronic integrated circuit chip 320 and side surfaces of the photonic block 330. Since the coating layer 340 is formed between the molding layer 350 and the photonic block 330, the molding layer 350 may be arranged to surround and/or be provided on the side surfaces of the photonic block 330 with the coating layer 340 arranged therebetween. For example, the top surface of molding layer 350 may be located on the same level as the top surface of electronic integrated circuit chip 320 and the top surface of photonic block 330 in the vertical direction (Z direction).

The molding layer 350 may include, for example, a thermosetting resin, such as an epoxy resin, a thermoplastic resin, such as polyimide, or a resin including an inorganic filler, specifically Ajinomoto build-up film (ABF), flame retardant 4 (FR-4), bismaleimide triazine (BT), a resin, or the like. In addition, a molding material, such as epoxy molding compound (EMC), or a photosensitive material, such as photo-imageable encapsulant (PIE), may be used.

The redistribution structure 360 may be arranged below the photonic integrated circuit chip 310 in the vertical direction (Z direction). The redistribution structure 360 may include a structure that electrically connects the photonic integrated circuit chip 310 to the second package substrate 200. The redistribution structure 360 may be provided on the wiring layer 220 of the second package substrate 200. According to one or more embodiments, the redistribution structure 360 may include a redistribution insulating layer 362 and redistribution patterns 364. The redistribution insulating layer 362 may be provided to be stacked in the vertical direction (Z direction), and the redistribution patterns 364 may be provided in the redistribution insulating layer 362. The redistribution insulating layer 362 may be formed from a PID or a PSPI, and the redistribution patterns 364 may include, but are not limited to, a metal, such as Cu, Al, W, Ti, Ta, indium (In), molybdenum (Mo), manganese (Mn), cobalt (Co), tin (Sn), Ni, magnesium (Mg), rhenium (Re), beryllium (Be), gallium (Ga), ruthenium (Ru), and the like, or an alloy thereof. In one or more embodiments, the redistribution patterns 364 may be formed by laminating a metal or an alloy thereof on a seed layer comprising Cu, Ti, TiN, or TiW. The photonic integrated circuit chip 310 and the second package substrate 200 may exchange electrical signals through the redistribution patterns 364 of the redistribution structure 360.

According to one or more embodiments, the connection terminals 370 may be disposed on the bottom surface of the redistribution structure 360. The connection terminal 370 may include a chip pad 372 disposed on the bottom surface of the redistribution structure 360 in the horizontal direction (X direction and Y direction) and a chip bump 374 disposed on the chip pad 372.

The chip pads 372 may be located on the bottom surface of the redistribution structure 360 to provide terminals at which the chip bumps 374 are to be placed. In one or more embodiments, the material of chip pads 372 may include Al. However, the material of chip pads 372 is not limited thereto. The material of the chip pads 372 may include a metal, such as Ni, Cu, Au, Ag, W, Ti, Ta, In, Mo, Mn, Co, Sn, Mg, Re, Be, Ga, Ru, and the like, or an alloy thereof.

The chip bumps 374 may be terminals for electrically connecting the photonic chip structure 300 to the second package substrate 200. In one or more embodiments, the chip bumps 374 may include solders of a metal material comprising at least one of Sn, Ag, Cu, and Al.

The aforementioned photonic chip structure 300 together with the first chip structure 400 and the second chip structures 500 may be disposed on the first package substrate 100 through the second package substrate 200. Hereinafter, the first package substrate 100, the second package substrate 200, the first chip structure 400, the second chip structures 500, and the package molding layer 600 are described in sequence.

The first package substrate 100 may include a substrate on which the second package substrate 200 is mounted. In one or more embodiments, the first package substrate 100 may include a motherboard on which various types of semiconductor chips and packages are mounted. In one or more embodiments, the first package substrate 100 may include a substrate that receives electrical signals from the second package substrate 200 and transmits the electrical signals to an external device.

According to one or more embodiments, the first package substrate 100 may include a printed circuit board (PCB) including a wiring pattern therein and an insulating layer surrounding and/or provided on the wiring pattern. In this case, the wiring pattern may include Cu, Ni, stainless steel, or BeCu, and the insulating layer may include at least one material selected from a phenol resin, an epoxy resin, and a polyimide. The insulating layer may include, for example, at least one material selected from among FR-4, tetrafunctional epoxy, polyphenylene ether, epoxy/polyphenylene oxide, BT, Thermount, cyanate ester, polyimide, and liquid crystal polymer.

The second package substrate 200 may be mounted on the first package substrate 100. The first chip structure 400, the second chip structures 500, and the photonic chip structures 300 may be mounted on the top surface of the second package substrate 200. The second package substrate 200 may electrically connect between the first chip structure 400, the second chip structures 500, and the photonic chip structures 300. In addition, the second package substrate 200 may be electrically connected to the first package substrate 100 through connection terminals 230. The second package substrate 200 may electrically connect the first chip structure 400, the second chip structures 500, and the photonic chip structures 300 to the first package substrate 100.

In one or more embodiments, the second package substrate 200 may include an interposer substrate. The second package substrate 200 may include a body layer 210 and a wiring layer 220. The wiring layer 220 may be located on the top surface of the body layer 210. Through electrodes 215 may be formed inside the body layer 210. The through electrodes 215 may penetrate the body layer 210 in the vertical direction (Z direction). According to one or more embodiments, the through electrode 215 may include, for example, a through silicon via (TSV). The wiring layer 220 may include a wiring pattern 225. The wiring pattern 225 may electrically connect the first chip structure 400, the second chip structures 500, and the photonic chip structures 300 to each other, electrically connect the first chip structure 400, the second chip structures 500, and the photonic chip structures 300, or electrically connect between the first chip structure 400 and the through electrodes 215, between the second chip structures 500 and the through electrodes 215, and between the photonic chip structures 300 and the through electrodes 215. The through electrodes 215 may be electrically connected to the first package substrate 100 through pads and bumps formed on the bottom surface of the body layer 210.

The second package substrate 200 is described as a silicon interposer including, but not limited to, a TSV. The second package substrate 200 may include, for example, a glass interposer including a through glass via (TGV).

In addition, in one or more embodiments, the second package substrate 200 may include a redistribution structure including a redistribution pattern and a redistribution insulating layer surrounding and/or provided on the redistribution pattern. The redistribution insulating layer may include an insulating material, for example, a photo imageable dielectric (PID) resin. In one or more embodiments, the redistribution insulating layer may further include an inorganic filler. In one or more embodiments, the redistribution insulating layer may have a multilayer structure in which the redistribution pattern is arranged in each layer. The redistribution pattern may include a redistribution line pattern extending in the horizontal direction (X direction and/or Y direction) and a redistribution via pattern extending from the redistribution line pattern in the vertical direction (Z direction). The redistribution line pattern may be disposed on at least one of the top surface and the bottom surface of the redistribution insulating layer or inside the redistribution insulating layer. The redistribution via pattern may be connected to a portion of the redistribution line pattern through the redistribution insulating layer. The redistribution pattern may include a conductive material, for example, Cu, Al, Ag, Sn, Au, Ni, lead (Pb), Ti, or an alloy thereof.

The photonic chip structures 300, the first chip structure 400, and the second chip structures 500 may be mounted on the top surface of the second package substrate 200. According to one or more embodiments, the photonic chip structures 300 may be located in an outer portion (peripheral portion) of the top surface of the second package substrate 200.

In one or more embodiments, the first chip structure 400 may be arranged at and/or adjacent to a center portion of the top surface of the second package substrate 200, and the second chip structures 500 may be disposed on both sides of the first chip structure 400 by being spaced apart from the first chip structure 400 in the first horizontal direction (X direction). The photonic chip structures 300 may be spaced apart from the first chip structure 400 in the second horizontal direction (Y direction).

In FIG. 1, the semiconductor package 10 is shown to include one first chip structure 400, four second chip structures 500, and four photonic chip structures 300, but the number of first chip structures 400, the number of second chip structures 500, and the number of photonic chip structures 300 included in the semiconductor package 10 are not limited thereto. In addition, for example, the semiconductor package 10 may include only one of the second chip structures 500 and the first chip structure 400.

The first chip structure 400 may include a first chip body 410, first chip pads 420, and first chip bumps 430. Herein, the first chip structure 400 may include a non-memory chip structure including a non-memory device. The first chip body 410 may include, for example, silicon. As another example, the first chip body 410 may include a semiconductor element, such as germanium, or a compound semiconductor, such as silicon carbide (SiC), gallium arsenide (GaAs), indium arsenide (InAs), and indium phosphide (InP). As another example, the first chip body 410 may have a silicon on insulator (SOI) structure. For example, the first chip body 410 may include a BOX. The first chip body 410 may include a conductive region, for example, an impurity-doped well or an impurity doped structure. In addition, the first chip body 410 may have various device isolation structures, such as a shallow trench isolation (STI) structure.

The first chip structure 400 may include, for example, a system-on-chip, a central processing unit (CPU) chip, a graphics processing unit (GPU) chip, or an application processor (AP) chip. The first chip structure 400 may execute applications supported by the semiconductor package 10 using a memory device included in the second chip structure 500. For example, the first chip structure 400 may include at least one processor of a CPU, an AP, a GPU, a neural processing unit (NPU), a tensor processing unit (TPU), a vision processing unit (VPU), an image signal processor (ISP), and a digital signal processor (DSP) to execute specialized operations.

According to one or more embodiments, the first chip pads 420 may be arranged on the bottom surface of the first chip body 410 in the horizontal direction (X direction and/or Y direction). According to one or more embodiments, the top surfaces of the first chip pads 420 may be coplanar with the bottom surface of the first chip body 410, and the first chip pads 420 may be in contact with the first chip bumps 430. The first chip bumps 430 may be provided between the second package substrate 200 and the first chip pads 420. Through the second package substrate 200, the first chip pads 420 may receive electrical signals from the second chip structures 500 or the photonic chip structures 300 or may transmit electrical signals to the second chip structures 500 or the photonic chip structures 300.

The first chip pads 420 may include a conductive material that may include, for example, Cu, Au, Ag, Ni, W, Al, or a combination thereof. In some embodiments, the first chip pads 420 may further include a barrier material for preventing the conductive material from diffusing out of the first chip pads 420. The barrier material may include, for example, Ti, Ta, TiN, TaN, or a combination thereof.

According to one or more embodiments, the first chip bumps 430 may be attached to the first chip pads 420 of the first chip body 410. The first chip bumps 430 may include a conductive material including, for example, Sn, Pb, Ag, Cu, or a combination thereof. The first chip bumps 430 may be formed, for example, using solder balls. The first chip bumps 430 may connect the first chip structure 400 to the second package substrate 200.

According to one or more embodiments, a first underfill material layer 440 may be further disposed on the bottom surface of the first chip body 410. The first underfill material layer 440 may be arranged to surround and/or be provided on the first chip bumps 430 between the second package substrate 200 and the first chip structure 400. For example, the first underfill material layer 440 may be formed by any one of, for example, a capillary underfill process, an o-flow underfill process, a molded underfill process, and a non-conductive film process. The first underfill material layer 440 may have a tapered shape in which a horizontal width decreases in the vertical direction (Z direction) from the second package substrate 200 toward the first chip body 410.

The second chip structure 500 may include a second chip body 510, second chip pads 520, and second chip bumps 530. Herein, the second chip structure 500 may include a memory chip structure including a memory device. The second chip body 510 may include, for example, silicon. As another example, the first chip body 410 may include a semiconductor element, such as germanium, or a compound semiconductor, such as SiC, GaAs, InAs, and InP. As another example, the second chip body 510 may have an SOI structure. For example, the second chip body 510 may include a BOX. The second chip body 510 may include a conductive region, for example, an impurity-doped well or an impurity doped structure. In addition, the second chip body 510 may have various device isolation structures, such as an STI structure.

The second chip structure 500 may include, for example, dynamic random-access memory (DRAM), static random-access memory (SRAM), flash memory, electrically erasable and programmable read-only memory (EEPROM), phase-change random-access memory (PRAM), magnetic random-access memory (MRAM), or resistive random-access memory (RRAM). According to one or more embodiments, the second chip structure 500 may include a memory cell chip having cells of high bandwidth memory (HBM) DRAM.

According to one or more embodiments, the second chip pads 520 may be arranged side by side (X direction and/or Y direction) on the bottom surface of the second chip body 510. According to one or more embodiments, top surfaces of the second chip pads 520 may be coplanar with the bottom surface of the second chip body 510, and the second chip pads 520 may be in contact with the second chip bumps 530. The second chip bumps 530 may be between the second package structure 200 and the second chip pads 520. The second chip pads 520 may receive electrical signals from the first chip structure 400 or the photonic chip structures 300 through the second package substrate 200 or may transmit electrical signals to the first chip structure 400 or the photonic chip structures 300.

The second chip pads 520 may include a conductive material that may include, for example, Cu, Au, Ag, Ni, W, Al, or a combination thereof. In one or more embodiments, the second chip pads 520 may further include a barrier material for preventing the conductive material from diffusing out of the first chip pads 420. The barrier material may include, for example, Ti, Ta, TiN, TaN, or a combination thereof.

According to one or more embodiments, the second chip bumps 530 may be attached to the second chip pads 520 of the second chip body 510. The second chip bumps 530 may include a conductive material including, for example, Sn, Pb, Ag, Cu, or a combination thereof. The second chip bumps 530 may be formed, for example, using solder balls. The second chip bumps 530 may connect the second chip structure 500 to the second package substrate 200.

According to one or more embodiments, the second underfill material layer 540 may be further disposed on the bottom surface of the second chip body 510. The second underfill material layer 540 may be arranged to surround and/or be provided on the second chip bumps 530 between the second package substrate 200 and the second chip structure 500. For example, the second underfill material layer 540 may be formed by any one of a capillary underfill process, an o-flow underfill process, a molded underfill process, and a non-conductive film process. The second underfill material layer 540 may have a tapered shape in which a horizontal width decreases in the vertical direction (Z direction) from the second package substrate 200 toward the second chip body 510.

The first chip structure 400 and the second chip structure 500 are described as a non-memory chip structure and a memory chip structure, respectively, but are not limited thereto. In some embodiments, the first chip structure 400 may include a memory chip structure including a memory chip, and the second chip structure 500 may include a non-memory chip structure including a non-memory device.

The photonic chip structures 300 may be mounted on the second package substrate 200 at a distance from the first chip structure 400 and the second chip structures 500 in the horizontal direction (e.g., X direction and/or Y direction). In one or more embodiments, the photonic chip structures 300 may be mounted on the second package substrate 200 in a flip chip manner through the connection terminals 370, such as micro-bumps. According to one or more embodiments, an underfill material layer 380 surrounding and/or provided on the connection terminals 370 may be arranged between the photonic chip structure 300 and the second package substrate 200. The underfill material layer 380 may have substantially the same configuration as the first underfill material layer 440 and the second underfill material layer 540 described in the first chip structure 400 and the second chip structure 500, respectively.

The package molding layer 600 may be formed to surround and/or be provided on the first chip structure 400, the second chip structures 500, and the photonic chip structures 300 on the top surface of the second package substrate 200. In one or more embodiments, the package molding layer 600 may cover and/or be provided on side surfaces of each of the first chip structure 400, the second chip structures 500, and the photonic chip structures 300 and may not cover a top surface of each of the first chip structure 400, the second chip structures 500, and the photonic chip structures 300 and expose the top surfaces. The top surface of the package molding layer 600 may be coplanar with the top surface of each of the first chip structure 400, the second chip structures 500, and the photonic chip structures 300. In the same sense, the top surface of the package molding layer 600 may have the same vertical level as the top surface of each of the first chip structure 400, the second chip structures 500, and the photonic chip structures 300.

According to one or more embodiments, the package molding layer 600 may be formed from a thermosetting resin, such as an epoxy resin, a thermoplastic resin, such as polyimide, or a resin including a reinforcing material, such as an inorganic filler, for example, but not limited to, ABF, FR-4, BT, or the like. The package molding layer 600 may be formed of a molding material, such as EMC or a photosensitive material, such as PIE. In one or more embodiments, a portion of the package molding layer 600 may include an insulating material, such as, for example, a silicon oxide film, a silicon nitride film, or a silicon oxynitride film.

In one or more embodiments, the package molding layer 600 may fill a gap between the first chip structure 400, the second chip structures 500, and the photonic chip structures 300 and the second package substrate 200 through a molded underfill process. In this case, the first underfill material layer 440, the second underfill material layer 540, and the underfill material layer 380 may be omitted.

FIGS. 1 and 3 show the photonic chip structure 300 of FIG. 4 mounted thereon, but are not limited thereto. For example, in FIGS. 1 and 3, embodiments of various photonic chip structures described below may be mounted thereon.

FIG. 5 is a schematic cross-sectional view of a photonic chip structure 300A according to one or more embodiments.

The photonic chip structure 300A described with reference to FIG. 5 is an example of the photonic chip structure shown in FIGS. 1 and 3. Most components of the photonic chip structure 300A and materials constituting the components are the same as or similar to those described above with reference to FIG. 4 except for the coating layer. Therefore, for convenience of description, differences from the photonic chip structure 300 described with reference to FIG. 4 are mainly described.

Referring to FIG. 5, the photonic chip structure 300A may include the photonic integrated circuit chip 310, the electronic integrated circuit chip 320, the photonic block 330, a coating layer 340a, the molding layer 350, the redistribution structure 360, and the connection terminals 370.

The coating layer 340a may include a first coating layer 340_1 and a second coating layer 340_2. The first coating layer 340_1 may be in direct contact with the photonic block 330, and the second coating layer 340_2 may be in contact with the molding layer 350. For example, the second coating layer 340_2 together with the first coating layer 340_1 may configure the multilayer coating layer 340a. The multilayer coating layer 340a may prevent the optical signals inside the photonic block 330 from being scattered at the boundary surface of the photonic block 330. In addition, the multilayer coating layer 340a may prevent external light other than the optical signals to be transmitted by the photonic block 330, for example, the optical signals directly transmitted from the FAU, from entering the photonic block 330. For example, the coating layer 340a may block the external light entering the side surface of the photonic block 330 from the molding layer 350.

In one or more embodiments, the first coating layer 340_1 may be arranged to surround and/or be provided on the side surfaces of the photonic block 330. The first coating layer 340_1 may be arranged between the photonic block 330 and the second coating layer 340_2 to surround and/or be provided on the photonic block 330, thereby blocking optical signals inside the photonic block 330 from being scattered at the boundary surface of the photonic block 330. In one or more embodiments, the first coating layer 340_1 may be formed of a light-absorbing material. For example, the first coating layer 340_1 may include, but is not limited to, carbon black, TiN, SiCr, and a black resin. In one or more embodiments, the first coating layer 340_1 may cause the optical signals inside the photonic block 330 to be totally reflected at the boundary surface of the photonic block 330. For example, the first coating layer 340_1 may be formed of a material having a refractive index less than a refractive index of the photonic block 330.

In one or more embodiments, the second coating layer 340_2 may be arranged to surround and/or be provided on the photonic block 330 between the first coating layer 340_1 and the molding layer 350. The second coating layer 340_2 may block external light other than the optical signals received from the photonic block 330 by the FAU from entering the photonic block 330. In one or more embodiments, the second coating layer 340_2 may include a light-absorbing material or a light-reflecting material. For example, the second coating layer 340_2 may include, but is not limited to, carbon black, TiN, SiCr, and a black resin to absorb the external light. For example, the second coating layer 340_2 may reflect the external light to block the external light from entering the photonic block 330.

In addition, each of the first coating layer 340_1 and the second coating layer 340_2 may have a refractive index that gradually changes from the refractive index of the photonic block 330 so that the optical signals inside the photonic block 330 are not randomly reflected at the boundary surface of the photonic block 330. For example, when the photonic block 330 is a glass block and has a refractive index of about 1.5, the first coating layer 340_1 may include a material having a refractive index less than 1.5 and the second coating layer 340_2 may include a material having a refractive index less than that of the first coating layer 340_1.

Although FIG. 5 illustrates the first coating layer 340_1 and the second coating layer 340_2, the coating layer 340a may include two or more coating layers. In addition, although the coating layer 340a is shown to surround and/or be provided on the side surfaces of the photonic block 330, embodiments are not limited thereto. The multilayer coating layer 340a may be arranged to surround and/or be provided on at least a portion of the top surface and/or at least a portion of the bottom surface together with the side surfaces of the photonic block 330.

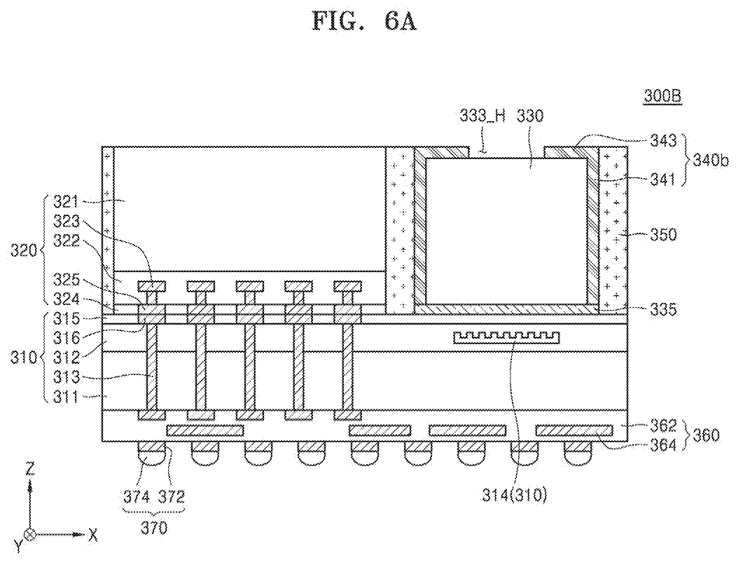

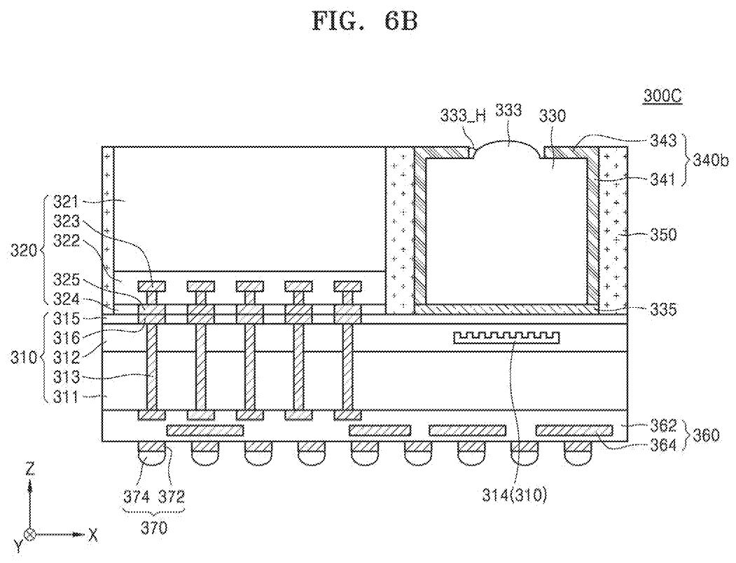

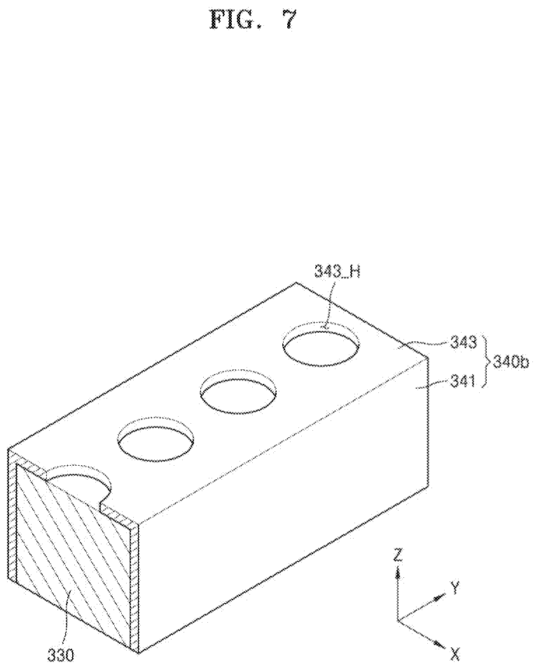

FIGS. 6A and 6B are schematic cross-sectional views of photonic chip structures 300B and 300C according to one or more embodiments. FIG. 7 is a schematic perspective view of the photonic block 330 and the coating layer 340b of FIG. 6A.

The photonic chip structures 300B and 300C described with reference to FIGS. 6A and 6B are examples of the photonic chip structure shown in FIGS. 1 and 3. Most components constituting the photonic chip structure and materials constituting the components are the same as or similar to those described above with reference to FIG. 4 except for the coating layer. FIG. 7 is a perspective view including cross sections of the photonic block 330 and the coating layer 340b cut vertically through openings 343_H. For convenience of description, differences from the photonic chip structure 300 described with reference to FIG. 4 are mainly described.

First, referring to FIG. 6A, the photonic chip structure 300B may include the photonic integrated circuit chip 310, the electronic integrated circuit chip 320, the photonic block 330, the coating layer 340b, the molding layer 350, the redistribution structure 360, and the connection terminals 370.

The coating layer 340b may include a first portion 341 that surrounds and/or is provided on the side surfaces of the photonic block 330 and a second portion 343 that covers and/or is provided on a portion of the top surface of the photonic block 330 while exposing another portion of the top surface of the photonic block 330.

The first portion 341 may be arranged between the photonic block 330 and the molding layer 350 to completely surround and/or be provided on the side surfaces of the photonic block 330. The first portion 341 may suppress the optical signals inside the photonic block 330 from being randomly reflected at the side boundary surface of the photonic block 330 and/or block the scattered light in the molding layer 350 other than the optical signals to be transmitted from entering the photonic block 330.

The second portion 343 may be arranged to cover and/or be provided on a portion of the top surface of the photonic block 330. For example, the second portion 343 may include the openings 343_H that are disposed on the top surface of the photonic block 330 and do not cover and expose the photonic block 330 so that the photonic block 330 may receive optical signals from the FAU. The opening 343_H may be formed at a position corresponding to the FAU. For example, the opening 343_H may be formed as a circular hole, but the shape thereof is not limited thereto. The second portion 343 may suppress the optical signals inside the photonic block 330 from being randomly reflected at the upper boundary surface of the photonic block 330 and/or block the external light other than the optical signals to be transmitted from entering the photonic block 330.

Since the second portion 343 is arranged to cover and/or be provided on a portion of the top surface of the photonic block 330, the photonic chip structure 300B may be formed such that the top surface of the electronic integrated circuit chip 320, the top surface of the second portion 343 of the coating layer 340b, and the top surface of the molding layer 350 are coplanar with each other.

Referring to FIG. 6B, the arrangement relationship between the photonic block 330 and the coating layer 340b in the case where microlenses 333 are formed on the top surface of the photonic block 330 is described.

The microlenses 333 may be disposed on the top surface of the photonic block 330. The microlenses 333 may be formed in a row or in multiple rows on the top surface of the photonic block 330. The microlens 333 may be arranged corresponding to the grating coupler 314 in the vertical direction (Z direction). The microlens 333 may be attached to the top surface of the photonic block 330 or may be integrally formed with the photonic block 330. Although FIG. 6B illustrates that the microlens 333 is convexly formed on the top surface of the photonic block 330, embodiments are not limited thereto. The microlens 333 may be concavely recessed and formed on the top surface of the photonic block 330.

The coating layer 340b may include the first portion 341 that surrounds and/or is provided on the side surfaces of the photonic block 330 and the second portion 343 that covers and/or is provided on a portion of the top surface of the photonic block 330. The second portion 343 may be disposed on the top surface of the photonic block 330 so as not to overlap with the microlenses 333 in the vertical direction (Z direction). For example, the second portion 343 may include the openings 343_H that do not cover and expose the photonic block 330 so that the photonic block 330 may receive optical signals from the FAU. The microlenses 333 may be formed to be located within the openings 343_H. However, the arrangement relationship between the microlenses 333 and the second portion 343 of the coating layer 340b is not limited thereto. For example, depending on the design, the microlenses 333 may be attached to the top surface of photonic block 330 to overlap with openings 343_H and portions of the second portion 343.

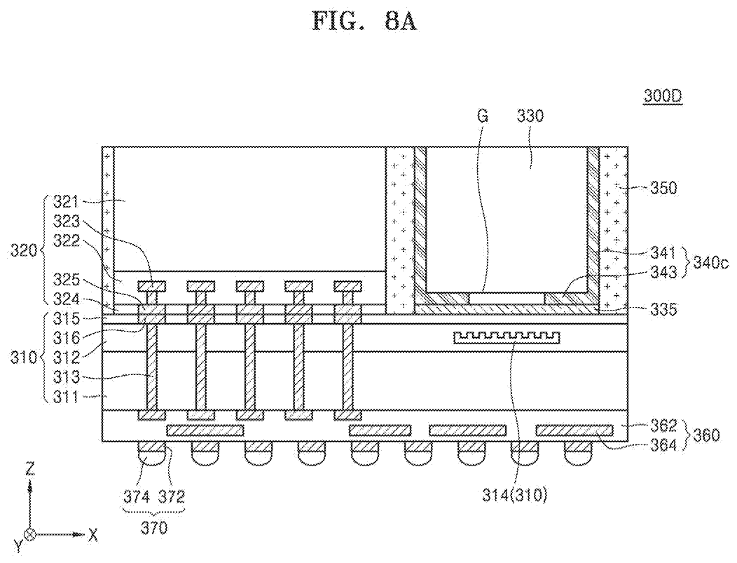

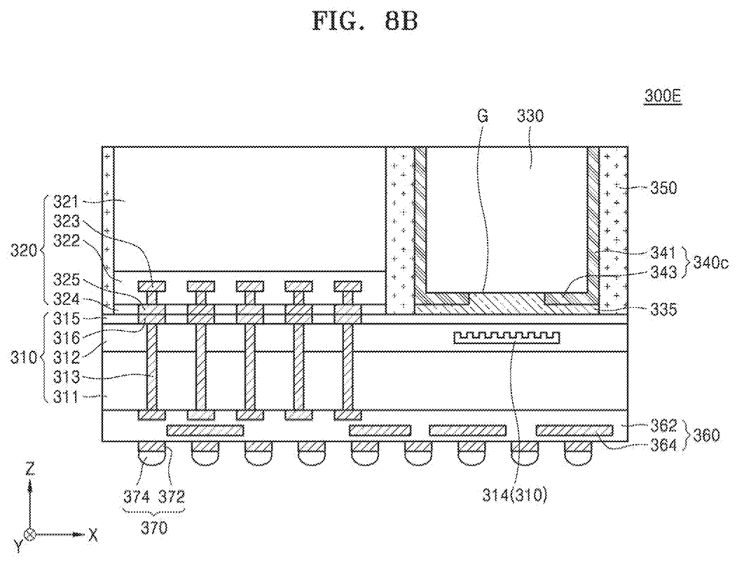

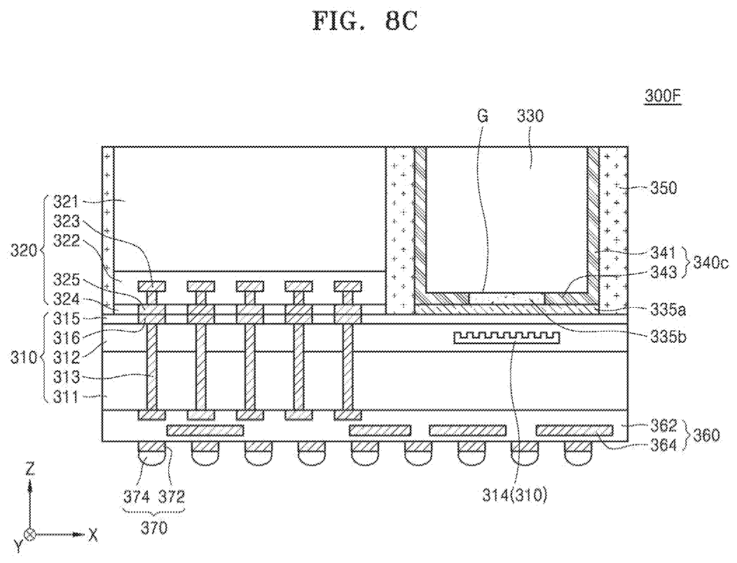

FIGS. 8A to 8C are schematic cross-sectional views of photonic chip structures 300D, 300E, and 300F according to one or more embodiments.

The photonic chip structures 300D, 300E, and 300F described with reference to FIGS. 8A to 8C are examples of the photonic chip structure shown in FIGS. 1 and 3. Most components constituting the photonic chip structure and materials constituting the components are the same as or similar to those described above with reference to FIG. 4 except for the coating layer. FIGS. 8A to 8C are different from each other in that a coating layer 340c including a first portion 341 and a third portion 343 is provided and photonic adhesive layers are arranged in different shapes. For convenience of description, FIG. 8A is first described, focusing on the difference from the photonic chip structure 300 described with reference to FIG. 4.

First, referring to FIG. 8A, the photonic chip structure 300D may include the photonic integrated circuit chip 310, the electronic integrated circuit chip 320, the photonic block 330, the coating layer 340c, the molding layer 350, the redistribution structure 360, and the connection terminals 370.

The coating layer 340c may include the first portion 341 that surrounds and/or is provided on the side surfaces of the photonic block 330 and the third portion 343 that covers and/or is provided on a portion of the bottom surface of the photonic block 330.

The first portion 341 may be arranged between the photonic block 330 and the molding layer 350 to completely surround and/or be provided on the side surfaces of the photonic block 330. The first portion 341 may suppress the optical signals inside the photonic block 330 from being randomly reflected at the side boundary surface of the photonic block 330 and/or block scattered light in the molding layer 350 other than the optical signals to be transmitted from entering the photonic block 330.

The third portion 343 may be arranged to cover and/or be provided on a portion of the bottom surface of the photonic block 330. For example, the third portion 343 may not cover the remaining portion of the bottom surface of the photonic block 330 and expose the remaining portion to transfer the optical signals inside the photonic block 330 to the photonic integrated circuit chip 310. The third portion 343 may suppress the optical signals inside the photonic block 330 from being randomly reflected at the lower boundary surface of the photonic block 330.

Since a portion of the third portion 343 is formed on the bottom surface of the photonic block 330, a gap G may be formed between the photonic block 330 and the photonic adhesive layer 335 in a portion where the third portion 343 does not cover and exposes the photonic block 330. The gap G may be formed at a position corresponding to the grating coupler 314 of the photonic integrated circuit chip 310. For example, the gap G may be formed as a circular hole, but the shape thereof is not limited thereto.

In one or more embodiments, when the OCA is provided on the bottom surface of the photonic block 330 as the photonic adhesive layer 335, the gap G between the bottom surface of photonic block 330 and the photonic adhesive layer 335 may be formed as an air layer.

Referring to FIG. 8B, in one or more embodiments, when the optical glue is provided on the bottom surface of the photonic block 330 as the photonic adhesive layer 335, the gap G between the bottom surface of the photonic block 330 and the photonic adhesive layer 335 may be filled with the photonic adhesive layer 335.

Referring to FIG. 8C, in one or more embodiments, a first photonic adhesive layer 335a and a second photonic adhesive layer 335b may be disposed on a bottom surface of the photonic block 330. As the first photonic adhesive layer 335a is disposed on the bottom surface of the third portion 343 of the coating layer 340c, the photonic block 330 on which the coating layer 340c is formed may be attached onto the photonic integrated circuit chip 310. For example, the first photonic adhesive layer 335a may include an OCA. The second photonic adhesive layer 335b may fill the gap G formed between the first photonic adhesive layer 335a and the bottom surface of the photonic block 330. For example, the second photonic adhesive layer 335b may include an optical glue.

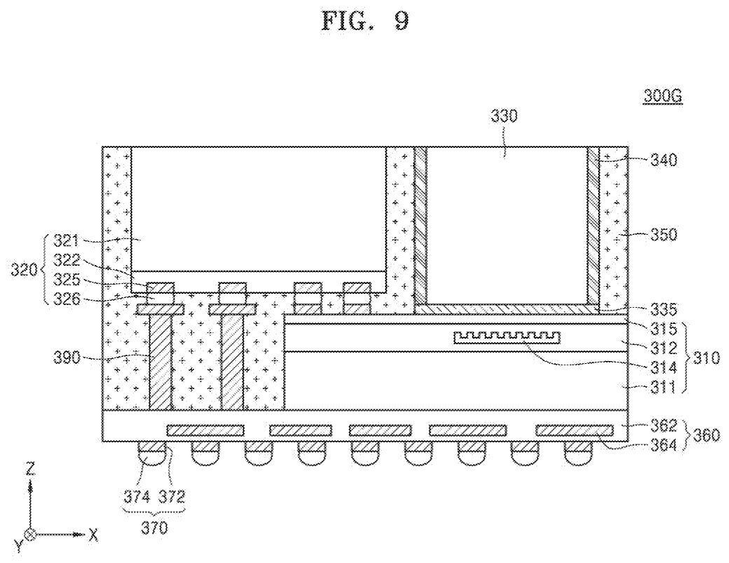

FIG. 9 is a schematic cross-sectional view of a photonic chip structure 300G according to one or more embodiments.

Referring to FIG. 9, the photonic chip structure 300G may include the photonic integrated circuit chip 310, the electronic integrated circuit chip 320, the photonic block 330, the coating layer 340, the molding layer 350, the redistribution structure 360, the connection terminals 370, and through posts 390.

The photonic block 330 of which the side surfaces are surrounded by the coating layer 340 may be attached to the photonic integrated circuit chip 310. The coating layer 340 may be arranged to surround and/or be provided on at least a side portion of the photonic block 330. The coating layer 340 may suppress the optical signals inside the photonic block 330 from being randomly reflected at the boundary surface of the photonic block 330 and/or prevent the external light of the photonic block 330 other than the optical signals to be transmitted or the scattered light in the molding layer 350 from entering the photonic block 330. Although FIG. 9 shows that the coating layer 340 is formed as a single layer on the side portion of the photonic block 330, it is not limited thereto. The coating layers of various embodiments described with reference to FIGS. 5 to 8C may be formed.

The electronic integrated circuit chip 320 may be arranged to be spaced apart from the photonic block 330 in the horizontal direction (X direction and/or Y direction), while being arranged to partially overlap the photonic integrated circuit chip 310 in the vertical direction (Z direction). Bumps 326 may be arranged below the second connection pads 325 of the electronic integrated circuit chip 320. The electronic integrated circuit chip 320 may be electrically connected to the through posts 390 through the bumps 326.

The through posts 390 may be arranged to extend in the vertical direction (Z direction) between the redistribution structure 360 and the electronic integrated circuit chip 320. The through posts 390 may electrically connect the electronic integrated circuit chip 320 to the redistribution structure 360. The through posts 390 may include, for example, Cu. However, the material of the through posts 390 is not limited to Cu.

Although FIG. 9 schematically illustrates a case where the electronic integrated circuit chip 320 partially overlaps the photonic integrated circuit chip 310 in the vertical direction (Z direction), embodiments are not limited thereto.

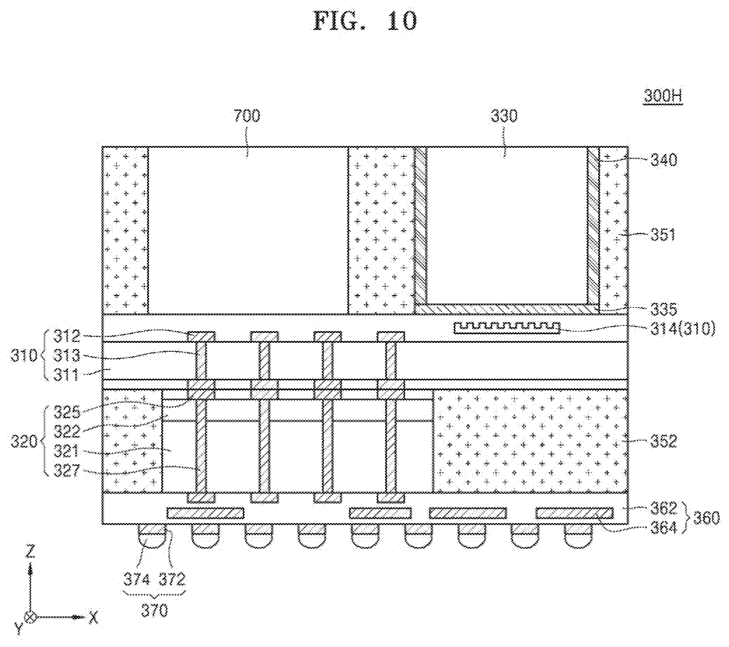

FIG. 10 is a schematic cross-sectional view of a photonic chip structure 300H according to one or more embodiments.

Referring to FIG. 10, the photonic chip structure 300H may include the photonic integrated circuit chip 310, the electronic integrated circuit chip 320, the photonic block 330, the coating layer 340, the molding layer 350, the redistribution structure 360, the connection terminals 370, and a dummy chip 700.

The electronic integrated circuit chip 320 may be arranged below the photonic integrated circuit chip 310 in the vertical direction (Z direction). The electronic integrated circuit chip 320 may be arranged below the photonic integrated circuit chip 310 to be electrically connected to the photonic integrated circuit chip 310. For example, the electronic integrated circuit chip 320 may include through electrodes 327 that penetrate the second substrate 321. The through electrodes 327 extend through the second substrate 321, and lower ends of the through electrodes 327 in contact with connection pads may be electrically connected to the redistribution structure 360.

The photonic block 330 and the dummy chip 700 may be disposed on the photonic integrated circuit chip 310. The coating layer 340 may be disposed on a side portion of the photonic block 330. The coating layer 340 may suppress the optical signals inside the photonic block 330 from being randomly reflected at the boundary surface of the photonic block 330 and/or prevent the external light of the photonic block 330 other than the optical signals to be transmitted or the scattered light in the molding layer 350 from entering the photonic block 330. Although FIG. 10 shows that the coating layer 340 is formed as a single layer on the side portion of the photonic block 330, it is not limited thereto. The coating layers of various embodiments described with reference to FIGS. 5 to 8C may be formed thereon.

The dummy chip 700 may be disposed on the photonic integrated circuit chip 310 to be spaced apart from the photonic block 330 in the horizontal direction (X direction and/or Y direction). The dummy chip 700 may be formed of, for example, silicon. For example, the dummy chip 700 may be disposed on the photonic integrated circuit chip 310 to ensure structural stability and form a path for dissipating heat generated from the photonic integrated circuit chip 310.

The photonic chip structures 300A, 300B, 300C, 300D, 300E, and 300F described above with reference to FIGS. 5 to 10 may replace the photonic chip structure 300 illustrated in the semiconductor package 10 of FIGS. 1 to 3.

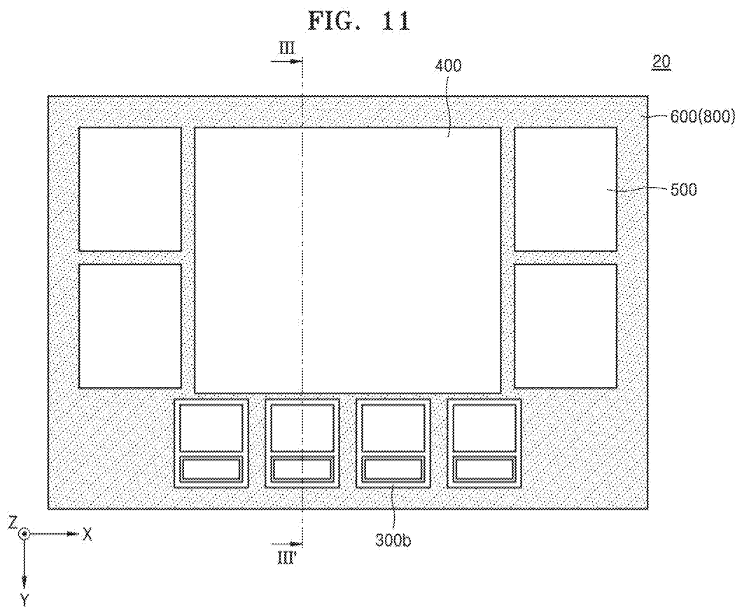

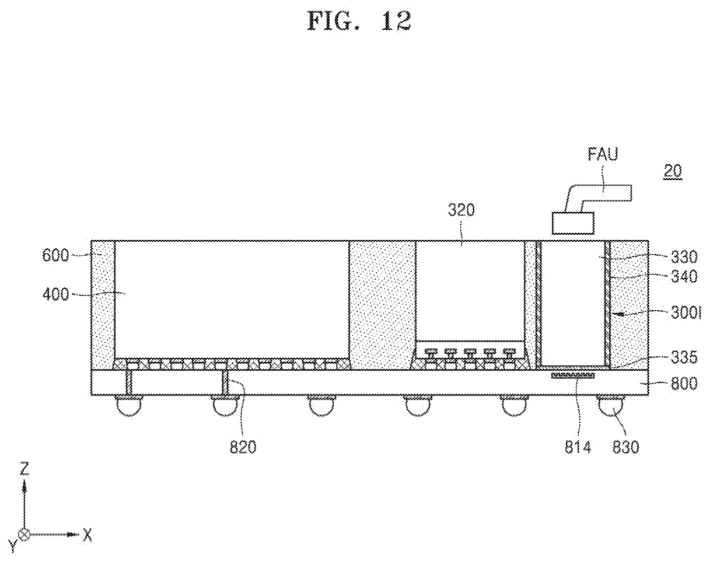

FIG. 11 is a schematic plan view of a semiconductor package 20 according to one or more embodiments. FIG. 12 is a schematic cross-sectional view of the semiconductor package 20 of FIG. 11 taken along line III-III′.

Referring to FIGS. 11 and 12, the semiconductor package 20 may include a photonic interposer 800, a photonic chip structure 300I, the first chip structure 400, the second chip structures 500, and the package molding layer 600. The semiconductor package 20 may include a semiconductor package that communicates with an external device through optical signals.

The first chip structure 400, the second chip structures 500, and the photonic chip structure 300I may be mounted on the photonic interposer 800. The first chip structure 400, the second chip structures 500, and the photonic chip structure 300I may be disposed on the photonic interposer 800 to be spaced apart from each other in the horizontal direction (X direction and/or Y direction). The photonic interposer 800 may electrically connect the first chip structure 400, the second chip structures 500, and the photonic chip structure 300I. In one or more embodiments, the photonic interposer 800 may receive electrical signals from the first chip structure 400, the second chip structures 500, and the photonic chip structure 300I and transmit the electrical signal to an external device. In one or more embodiments, a through electrode 820 may be formed inside the photonic interposer 800 to be electrically connected to the first chip structure 400 and the second chip structures 500.

In one or more embodiments, the photonic interposer 800 may function as the photonic integrated circuit chip 310 of the photonic chip structure 300 described with reference to FIG. 4. A grating coupler 814 may be embedded in the photonic interposer 800. The grating coupler 814 may be arranged to be aligned with the photonic block 330. For example, the grating coupler 814 may be arranged within the photonic interposer 800 to vertically overlap the photonic block 330 in the vertical direction (Z direction).

According to one or more embodiments, the electronic integrated circuit chip 320 may be mounted on the photonic interposer 800. The electronic integrated circuit chip 320 may be disposed on the photonic interposer 800 to be spaced apart from the photonic block 330 in the horizontal direction (X direction and/or Y direction).

The photonic block 330 may be located on the photonic interposer 800. For example, the photonic block 330 may be located on the photonic interposer 800 to be spaced apart from the electronic integrated circuit chip 320 in the first horizontal direction (X direction). The photonic block 330 may be located above the grating coupler 814 of the photonic interposer 800 in the vertical direction (Z direction).

The coating layer 340 may be disposed on the surface of the photonic block 330. The coating layer 340 may be formed on at least a portion of the surface of the photonic block 330. The coating layer 340 may suppress the optical signals inside the photonic block 330 from being randomly reflected at the boundary surface of the photonic block 330 and/or prevent the external light of the photonic block 330 other than the optical signals to be transmitted or the scattered light in the molding layer 350 from entering the photonic block 330.

Although FIG. 12 shows that the coating layer 340 is formed as a single layer on the side surface of the photonic block 330, it is not limited thereto. The coating layers of various embodiments described with reference to FIGS. 5 to 8C may be formed thereon.

The package molding layer 600 may be formed to surround and/or be provided on the first chip structure 400, the second chip structures 500, and the photonic chip structure 300I on the top surface of the photonic interposer 800. In one or more embodiments, the package molding layer 600 may cover and/or be provided on side surfaces of each of the first chip structure 400, the second chip structures 500, and the photonic chip structure 300I, and may not cover and expose a top surface of each of first chip structure 400 and the second chip structure 300I and expose the top surfaces.

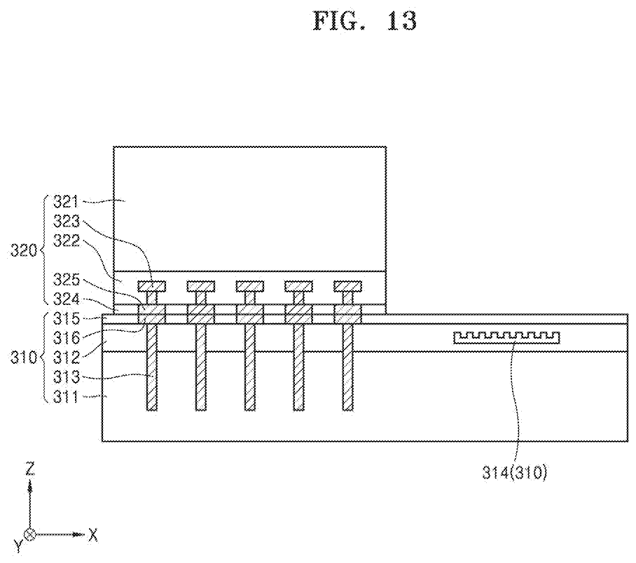

FIGS. 13 to 18 are schematic diagrams illustrating a process of a method of manufacturing the semiconductor package 10 of FIGS. 1 to 3.

Referring to FIG. 13, the photonic integrated circuit chip 310 may be prepared, and the electronic integrated circuit chip 320 may be attached onto the photonic integrated circuit chip 310. The electronic integrated circuit chip 320 may be attached onto the photonic integrated circuit chip 310 in a face-down manner so that the wiring structures 323 and the active surface of the electronic integrated circuit chip 320 face the photonic integrated circuit chip 310. The electronic integrated circuit chip 320 may be coupled onto the photonic integrated circuit chip 310 such that the second connection pads 325 are coupled to the first connection pads 316 of the photonic integrated circuit chip 310.

In one or more embodiments, the photonic integrated circuit chip 310 may be coupled onto the electronic integrated circuit chip 320 by, for example, hybrid bonding. In this case, the first connection pads 316 may be coupled to the second connection pads 325 by heat diffusion bonding.

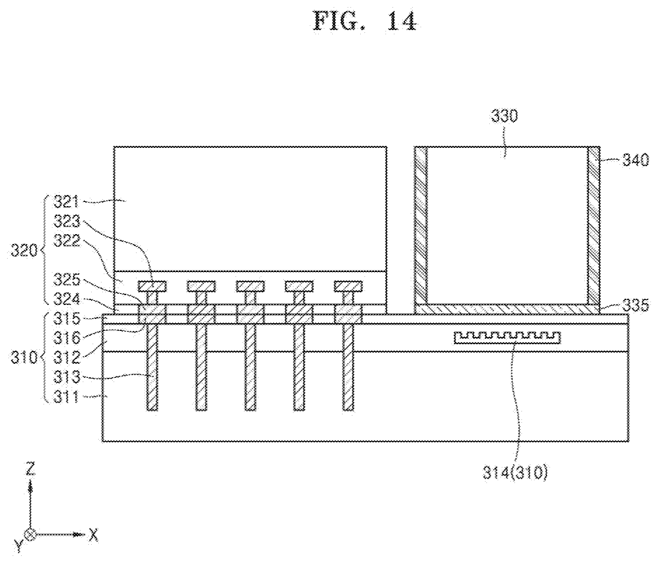

Referring to FIG. 14, the photonic block 330 having the coating layer formed thereon is attached onto the photonic integrated circuit chip 310. The coating layer 340 may be disposed on the surface of the photonic block 330. The forming of the coating layer 340 on the photonic block 330 may be performed in any step before attaching the photonic block 330 onto the photonic integrated circuit chip 310. The coating layer 340 may include a material including a light-absorbing material or a material including a refractive index less than a refractive index of the photonic block 330. The coating layer 340 may suppress the optical signals inside the photonic block 330 from being randomly reflected at the boundary surface of the photonic block 330 and/or prevent the external light of the photonic block 330 other than the optical signals to be transmitted or the scattered light in the molding layer 350 from entering the photonic block 330.

The photonic block 330 may be attached onto the photonic integrated circuit chip 310 via the photonic adhesive layer 335. The photonic adhesive layer 335 may include an OCA or an optical glue.

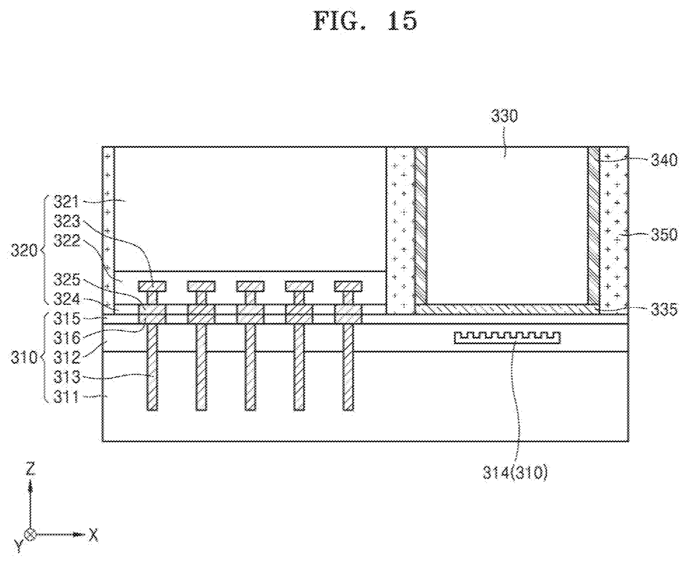

Referring to FIG. 15, the molding layer 350 is formed on the photonic integrated circuit chip 310. The molding layer 350 may seal the electronic integrated circuit chip 320 and the photonic block 330 on the photonic integrated circuit chip 310. The molding layer 350 may cover and/or be provided on the top surface of the first passivation layer 315 of the photonic integrated circuit chip 310 and surround and/or be provided on the side surfaces of the electronic integrated circuit chip 320 and the side surfaces of the photonic block 330. The molding layer 350 may include, for example, a thermosetting resin, such as an epoxy resin, a thermoplastic resin, such as polyimide, or a resin including an inorganic filler, specifically ABF, FR-4, BT, a resin, or the like. In addition, a molding material, such as EMC, or a photosensitive material, such as PIE, may be used.

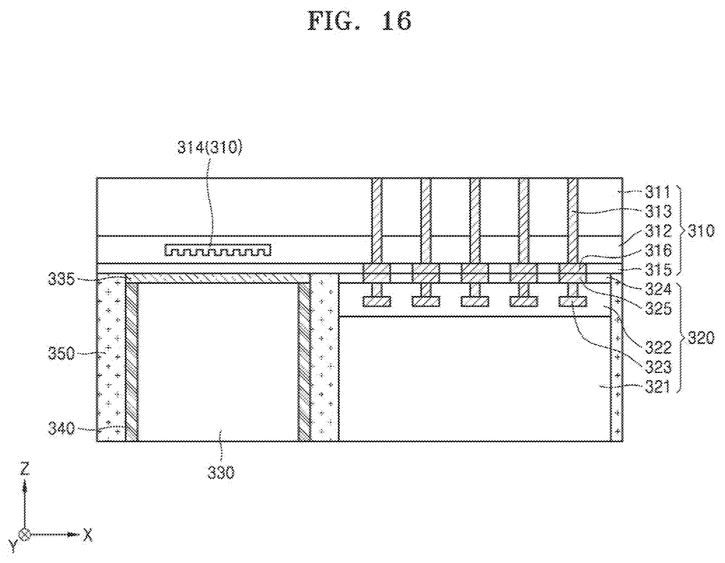

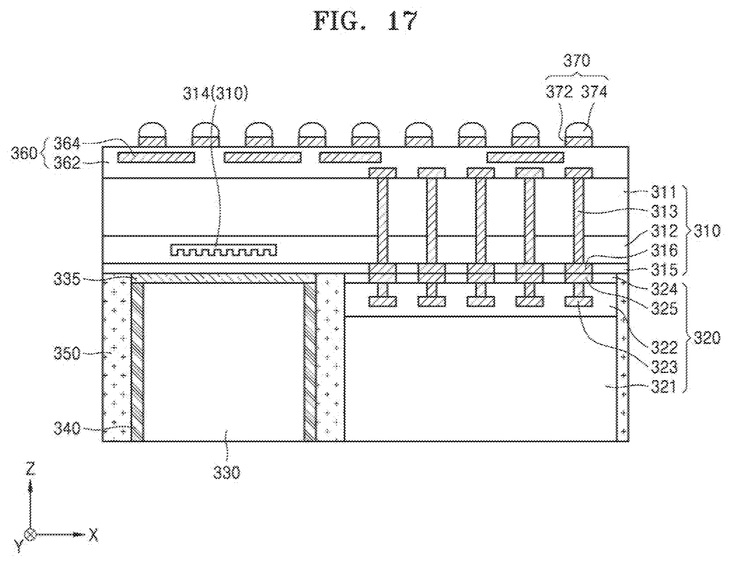

Referring to FIGS. 16 and 17, the photonic chip structure of FIG. 15 is inverted to grind the first substrate 311 of the photonic integrated circuit chip 310 so that the through electrodes 313 are exposed from the first substrate 311. The process of grinding the first substrate 311 may be understood as a back grinding process and a process of thinning the first substrate 311. When the through electrodes 313 are exposed from the first substrate 311, the redistribution structure 360 is formed on the first substrate 311. The redistribution structure 360 may include the redistribution insulating layer 362 and the redistribution patterns 364, wherein the redistribution patterns 364 may be connected to the exposed through electrodes 313. Then, the connection terminals 370 are formed on the redistribution structure 360.

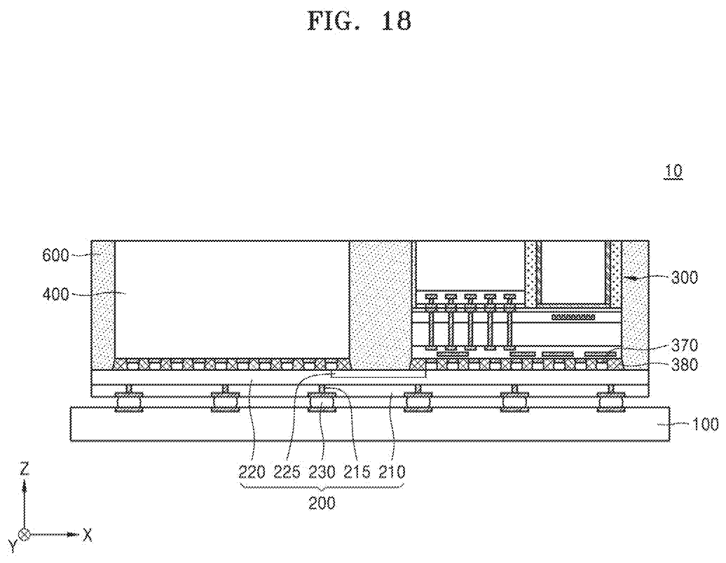

Referring to FIG. 18, the photonic chip structures 300, the first chip structure 400, and the second chip structures 500 of FIG. 17 are mounted on the second package substrate 200. Then, the package molding layer 600 is formed on the second package substrate 200. The package molding layer 600 may cover and/or be provided on the first chip structure 400, the second chip structures 500, and the photonic chip structure 300. Then, the second package substrate 200 on which the first chip structure 400, the second chip structures 500, and the photonic chip structure 300 are mounted may be attached onto the first package substrate 100. In addition, the FAU is disposed above the photonic block 330 so that external optical signals may enter the photonic block 330 through the optical fiber of the FAU.

According to one or more embodiments, the photonic chip structure 300 with improved quality of optical signals, including the coating layer 340 covering and/or being provided on at least the side surface of the photonic block 330, and the semiconductor package 10 including the same may be provided. For example, in the photonic chip structure 300 according to embodiments, the light inside the photonic block 330 is not randomly reflected or scattered at the boundary surface of the photonic block 330 and unnecessary external light is suppressed from flowing in, thereby reducing scattered light and optical interference of the optical device. Accordingly, the photonic chip structure 300 and the semiconductor package 10 that minimize noise and signal distortion due to external light interference and reduce light loss, thereby improving the quality and detection accuracy of the optical signals.

While embodiments have been described with reference to the figures, it will be understood by those of ordinary skill in the art that various changes in form and details may be made therein without departing from the spirit and scope as defined by the following claims and their equivalents.

What is claimed is:

1. A photonic chip structure comprising:
a photonic integrated circuit chip;
an electronic integrated circuit chip connected to the photonic integrated circuit chip;
a photonic block on the photonic integrated circuit chip and provides a path for optical signals;
a coating layer on at least a side surface of the photonic block and suppresses scattering of optical signals inside the photonic block; and
a molding layer on the photonic integrated circuit chip and a side surface of the photonic block, the coating layer being between the molding layer and the photonic block.

2. The photonic chip structure of claim 1, wherein the coating layer comprises a first portion on a side surface of the photonic block and a second portion on a portion of a top surface of the photonic block.

3. The photonic chip structure of claim 2, wherein a fiber array unit, provides optical signals to the photonic block, is disposed on the photonic block, and
wherein the second portion of the coating layer comprises an opening that does not overlap with a path for optical signals provided in the fiber array unit.

4. The photonic chip structure of claim 1, wherein the coating layer comprises a first portion on a side surface of the photonic block and a third portion on a portion of a bottom surface of the photonic block.

5. The photonic chip structure of claim 4, further comprising an optically clear adhesive on a bottom surface of the third portion of the coating layer and bonds the third portion of the coating layer to the photonic integrated circuit chip,
wherein a gap is formed between the optically clear adhesive and a portion of the bottom surface of the photonic block that does not overlap with the third portion.

6. The photonic chip structure of claim 5, further comprising an optical glue filling the gap.

7. The photonic chip structure of claim 4, wherein the photonic block is on a bottom surface of the third portion of the coating layer and a portion of the bottom surface of the photonic block that does not overlap with the third portion, and
wherein the photonic block comprises an optically clear adhesive that bonds the photonic block and the third portion to the photonic integrated circuit chip.

8. The photonic chip structure of claim 1, wherein the coating layer comprises a first coating layer in contact with the photonic block and a second coating layer in contact with the molding layer,
wherein the first coating layer blocks scattering of internal optical signals of the photonic block, and the second coating layer blocks external light entering the photonic block.

9. The photonic chip structure of claim 8, wherein the first coating layer is formed of a light-absorbing material.

10. The photonic chip structure of claim 8, wherein the second coating layer comprises a light-absorbing material or a light-reflecting material.

11. The photonic chip structure of claim 1, wherein the electronic integrated circuit chip is on the photonic integrated circuit chip and spaced apart from the photonic block in a horizontal direction, and
wherein the photonic integrated circuit chip comprises:
a substrate,
an interlayer insulating layer comprising a grating coupler is on the substrate and aligned with the photonic block, and
a through electrode that penetrates the substrate and the interlayer insulating layer and is connected to the electronic integrated circuit chip.

12. A photonic chip structure comprising:
a photonic integrated circuit chip;
an electronic integrated circuit chip connected to the photonic integrated circuit chip;
a photonic block on the photonic integrated circuit chip and provides a path for optical signals;
a coating layer on at least a side surface of the photonic block, the coating layer having a refractive index less than a refractive index of the photonic block; and
a molding layer on the photonic integrated circuit chip and on a side surface of the photonic block, the coating layer being between the molding layer and the photonic block.

13. The photonic chip structure of claim 12, wherein the coating layer comprises a first portion on a side surface of the photonic block and a second portion on a portion of a top surface of the photonic block or a third portion on a portion of a bottom surface of the photonic block.

14. The photonic chip structure of claim 13, wherein a fiber array unit, provides optical signals to the photonic block, is on the photonic block, and
wherein the second portion of the coating layer comprises an opening that does not overlap with a path for optical signals provided in the fiber array unit.

15. The photonic chip structure of claim 12, wherein the photonic block comprises microlenses in a row or multiple rows on a top surface of the photonic block.

16. The photonic chip structure of claim 12, wherein a top surface of the photonic block is coplanar with a top surface of the molding layer.

17. The photonic chip structure of claim 12, wherein the coating layer comprises a first coating layer in contact with the photonic block and a second coating layer in contact with the molding layer,
wherein a refractive index of the first coating layer is less than a refractive index of the photonic block, and
wherein a refractive index of the second coating layer is less than a refractive index of the first coating layer.

18. A semiconductor package comprising:
a package substrate;
a semiconductor chip structure on the package substrate; and
a photonic chip structure on the package substrate and spaced apart from the semiconductor chip structure in a horizontal direction,
wherein the photonic chip structure comprises:
a photonic integrated circuit chip;
an electronic integrated circuit chip connected to the photonic integrated circuit chip;
a photonic block on the photonic integrated circuit chip and provides a path for optical signals;
a coating layer on at least a side surface of the photonic block and supresses scattering of optical signals inside the photonic block; and
a molding layer on the photonic integrated circuit chip and on a side surface of the photonic block, the coating layer being between the molding layer and the photonic block.

19. The semiconductor package of claim 18, wherein the coating layer comprises a first coating layer in contact with the photonic block and a second coating layer in contact with the molding layer,
wherein the first coating layer blocks scattering of internal optical signals of the photonic block, and
wherein the second coating layer blocks external light from entering the photonic block.

20. The semiconductor package of claim 19, wherein the first coating layer has a refractive index greater than a refractive index of the photonic block or is formed of a light-absorbing material, and
wherein the second coating layer comprises a light-absorbing material or a light-reflecting material.
